(19) United States
(12) Patent Application Publication
(10) Pub. No.: US 2025/0068818 A1
(43) Pub. Date: Feb. 27, 2025

(54) EFFICIENT COMPONENT MAPPING FOR PROGRAMABLE LOGIC DEVICES, SYSTEMS, AND METHODS

(71) Applicant: Lattice Semiconductor Corporation, Hillsboro, OR (US)

(72) Inventors: Michael Schneider, San Jose, CA (US); Eileen Shen, San Jose, CA (US); Chih-Chung Chen, San Jose, CA (US)

(21) Appl. No.: 18/810,215

(22) Filed: Aug. 20, 2024

Related U.S. Application Data
(60) Provisional application No. 63/578,140, filed on Aug. 22, 2023.

(51) Int. Cl. G06F 30/373; G06F 30/392

(52) U.S. Cl. CPC G06F 30/373; G06F 30/392

(57) ABSTRACT

Various techniques are provided for efficiently mapping synthesized components to physical hardware components of a PLD. In one example, a method includes receiving a design identifying operations to be performed by a programmable logic device (PLD). The method also includes converting the operations to a plurality of synthesized components. The method also includes mapping a selected one of the synthesized components to a model associated with first and second types of hardware components of the PLD. The selected synthesized component is compatible with first and second specifications of the first and second types of hardware components, respectively. The method also includes assigning the selected synthesized component to a physical location of the PLD comprising either the first type of hardware component or the second type of hardware component to improve a performance metric of the PLD configured with the design. Additional devices, systems and methods are also provided.

### CROSS REFERENCE TO RELATED APPLICATIONS

This application claims priority to and the benefit of U.S. Provisional Patent Application No. 63/578,140 filed Aug. 22, 2023, and entitled “EFFICIENT COMPONENT MAPPING FOR PROGRAMABLE LOGIC DEVICES, SYSTEMS, AND METHODS,” which is incorporated herein by reference in its entirety.

### TECHNICAL FIELD

This disclosure relates generally to programmable logic devices and, more specifically, to generating configurations for programmable logic devices.

### BACKGROUND

Programmable logic devices (PLDs), such as field programmable gate arrays (FPGAs), complex programmable logic devices (CPLDs), field programmable systems on a chip (FPSCs), or other types of programmable devices may be configured with various designs to implement desired functionality. The designs may be converted into synthesized components that are assigned to physical hardware components of the PLD configured to implement the designs.

In some cases, several types of a particular kind of physical hardware component may be included in a PLD, but with different specifications. Thus, some synthesized components may be compatible with only one type of physical hardware component of the PLD, whereas other synthesized components may be compatible with multiple different types of physical hardware components of the PLD.

In conventional approaches, a synthesized component is typically mapped to any compatible physical hardware component, even if additional compatible physical hardware components are available. Unfortunately, such approaches fail to consider whether a particular one of the additional compatible physical hardware components may provide a superior implementation of the design, such as improvements in one or more performance metrics. As a result, conventional approaches may fail to fully achieve efficient PLD implementations of designs.

### SUMMARY

Various techniques are provided for efficiently mapping synthesized components to physical hardware components of a PLD. In one embodiment, a method includes receiving a design identifying operations to be performed by a programmable logic device (PLD); converting the operations to a plurality of synthesized components; mapping a selected one of the synthesized components to a model associated with first and second types of hardware components of the PLD, wherein the selected synthesized component is compatible with first and second specifications of the first and second types of hardware components, respectively; and assigning the selected synthesized component to a physical location of the PLD comprising either the first type of hardware component or the second type of hardware component to improve a performance metric of the PLD configured with the design.

In another embodiment, a system includes a processor; and a memory adapted to store a plurality of computer readable instructions which when executed by the processor are adapted to cause the system to perform a method comprising: receiving a design identifying operations to be performed by a programmable logic device (PLD), synthesizing the design into a plurality of synthesized components, mapping a selected one of the synthesized components to a model associated with first and second types of hardware components of the PLD, wherein the selected synthesized component is compatible with first and second specifications of the first and second types of hardware components, respectively, and assigning the selected synthesized component to a physical location of the PLD comprising either the first type of hardware component or the second type of hardware component to improve a performance metric of the PLD configured with the design.

### BRIEF DESCRIPTION OF THE DRAWINGS

FIG. 1 illustrates a block diagram of a PLD in accordance with an embodiment of the disclosure.

FIG. 2 illustrates a block diagram of a PLD implemented on a die with several types of input/output (I/O) blocks in accordance with an embodiment of the disclosure.

FIG. 3 illustrates a block diagram of a PLD showing various components of I/O blocks in accordance with an embodiment of the disclosure.

FIG. 4 illustrates a process of implementing a design for a PLD in accordance with an embodiment of the disclosure.

FIG. 5 illustrates a process of mapping components of a design for a PLD in accordance with an embodiment of the disclosure.

FIG. 6 illustrates a process of placing components of a design for a PLD in accordance with an embodiment of the disclosure.

Embodiments of the present disclosure and their advantages are best understood by referring to the detailed description that follows. It should be appreciated that like reference numerals are used to identify like elements illustrated in one or more of the figures.

### DETAILED DESCRIPTION

As discussed, PLDs may be configured with designs to implement desired functionality. In particular, the designs may be converted to synthesized components (e.g., logical constructs representing operations performed by the designs) that are mapped to models associated with one or more physical hardware components of the PLD (e.g., I/O buffers, I/O registers, programmable logic cells, embedded block random access memory (RAM), digital signal processor blocks, memories, registers, look-up tables (LUTs), gates, and/or other components discussed herein) that are configured to implement the designs. Using the models, the synthesized components are assigned to (e.g., placed at) physical locations of the PLD comprising physical hardware components associated with the models. Configuration data is generated to configure the assigned physical hardware components which is programmed into the PLD to configure the PLD for operation in accordance with the design implemented by the assigned physical hardware components.

As also discussed, several types of a particular kind of physical hardware component may be included in a PLD. For example, PLDs may include I/O buffers with different specifications (e.g., different operating voltage ranges, different operating data speed ranges, and/or others). For example, a first type of I/O buffer (e.g., a high performance I/O buffer 350 further discussed herein) may be implemented with high performance specifications to pass signals with small voltage ranges (e.g., 0.9 volts to 1.8 volts) and high speed data rate ranges (e.g., 500 Mbps to 1 Gbps). In contrast, a second type of I/O buffer (e.g., a legacy I/O buffer 320 further discussed herein) may be implemented with legacy specifications to pass signals with large voltage ranges (e.g., 1.2 volts to 3.3 volts) and low speed data rates (e.g., 100 Mbps or lower).

In the example above, if a design calls for an I/O buffer with a data rate greater than 100 Mbps, then the first type of I/O buffer would be used. Alternatively, if a design calls for an I/O buffer with a large voltage signal greater than 1.8 volts, then the second type of I/O buffer would be used.

However, it will be appreciated that there is overlap in the specifications of the first and second types of I/O buffers noted above. Thus, in some cases, an I/O buffer of a design may be implemented by either the first or second type of I/O buffer. For example, if an I/O buffer of a design is compatible with a voltage signal in the range of 1.2 volts to 1.8 volts and is also compatible with low speed data rates of 100 Mbps and high speed data rates of 500 Mbps to 1 Gbps, then either the first or second type of I/O buffer may be used in the implementation.

However, in such cases, arbitrarily selecting either the first or second type of I/O buffer may be detrimental to the implementation of the design. For example, in some PLDs, the different types of a particular kind of hardware component may be located at different physical locations of the PLD. Thus, arbitrarily selecting the first or second type of component may result in excessively long routing connections between the various components of the PLD with associated latencies that could be reduced if another type of component were selected.

In accordance with techniques of the present disclosure, if a design calls for a synthesized component having a specification that may be satisfied by multiple types of physical hardware components, then the synthesized component may be mapped to a multiple type model (e.g., also referred to as a common model) that is associated with those multiple types of physical hardware components (e.g., associated with both the high performance and the legacy I/O buffers in the example above). As a result, the synthesized component may be selectively assigned to any hardware locations of the PLD comprising any of the multiple types of physical hardware components to improve one or more performance metrics of the design such as the latency of signals passed to or from the physical hardware components.

For example, the synthesized component may be assigned to either a high performance I/O buffer or a legacy I/O buffer in order to satisfy performance metrics of the design based on the physical location of the buffer, rather than the voltage signals or data rates supported by the buffer. In this case, because both types of I/O buffers satisfy the synthesized component's specification, the design is agnostic to the buffer type used as the buffer types are fungible with respect to each other. Instead, the buffer may be assigned, for example, based on its physical location to reduce the length of routing connections and therefore reduce latency.

In contrast, if a design calls for a synthesized component having a specification that may be satisfied by only a single type of physical hardware component, then the synthesized component may be mapped to a single type model that is associated with only the single type of physical hardware component (e.g., associated with either the high performance or the legacy I/O buffers in the example above). As a result, the synthesized component may be assigned to only hardware locations of the PLD comprising the single type of physical hardware component.

In some embodiments, the synthesized components associated with single type models are assigned to physical locations before the synthesized components associated with multiple type models. As a result, the assignments of the multiple type models will not restrict the assignments of the single type models.

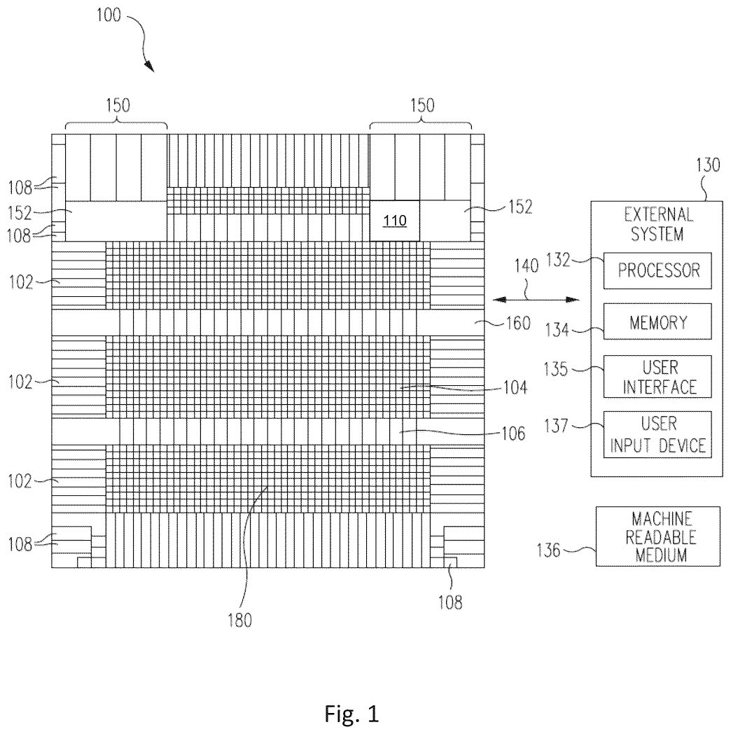

Referring now to the drawings, FIG. 1 illustrates a block diagram of a PLD 100 in accordance with an embodiment of the disclosure. PLD 100 (e.g., a field programmable gate array (FPGA)), a complex programmable logic device (CPLD), a field programmable system on a chip (FPSC), or other type of programmable device) generally includes various physical hardware components such as I/O (I/O) blocks 102, logic blocks 104 (e.g., also referred to as programmable logic blocks (PLBs), programmable functional units (PFUs), or programmable logic cells (PLCs)) and others as discussed.

I/O blocks 102 provide I/O functionality (e.g., to support one or more I/O and/or memory interface standards) for PLD 100, while logic blocks 104 provide logic functionality (e.g., look-up table (LUT) logic or logic gate array-based logic) for PLD 100. Additional I/O functionality may be provided by serializer/deserializer (SERDES) blocks 150 and physical coding sublayer (PCS) blocks 152. In various embodiments, I/O blocks 102 and SERDES blocks 150 may route signals to and from associated external ports (e.g., physical pins) of PLD 100. PLD 100 may also include hard intellectual property core (IP) blocks 160 to provide additional functionality (e.g., substantially predetermined functionality provided in hardware which may be configured with less programming than logic blocks 104).

PLD 100 may also include memory blocks 106 (e.g., blocks of EEPROM memory blocks, RAM (e.g., static and/or dynamic) memory blocks, and/or flash memory blocks), clock-related circuitry 108 (e.g., clock sources, PLL circuits, and/or DLL circuits), and/or various routing resources 180 (e.g., interconnect and appropriate switching logic to provide paths for routing signals throughout PLD 100, such as for clock signals, data signals, or others) as appropriate. In various embodiments, routing resources 180 may include user configurable routing resources and hardwired signal paths. In general, the various physical hardware components of PLD 100 may be used to perform their intended functions for desired applications, as would be understood by one skilled in the art.

For example, I/O blocks 102 may be used for programming PLD 100, such as memory blocks 106 (e.g., including volatile configuration memory) or transferring information (e.g., various types of data and/or control signals) to/from PLD 100 through various external ports as would be understood by one skilled in the art. I/O blocks 102 may provide a first programming port (which may represent a central processing unit (CPU) port, a peripheral data port, an SPI interface, and/or a sysCONFIG programming port) and/or a second programming port such as a joint test action group (JTAG) port (e.g., by employing standards such as Institute of Electrical and Electronics Engineers (IEEE) 1149.1 or 1532 standards). I/O blocks 102 typically, for example, may be included to receive configuration data and commands (e.g., over one or more connections 140) to configure PLD 100 for its intended use and to support serial or parallel device configuration and information transfer with SERDES blocks 150, PCS blocks 152, hard IP blocks 160, and/or logic blocks 104 as appropriate.

For example, in some embodiments any of the various components discussed herein may be configured in response to a configuration engine 110 (e.g., implemented by appropriate logic such as one or more processors, finite state machines, and/or other hardware and/or software) passing configuration data by routing resources 180. In some embodiments, configuration data may be stored locally on PLD 100, for example, in one or more memory blocks 106 and/or stored externally from PLD 100, for example in a memory 134 of an external system 130.

It should be understood that the number and placement of the various components are not limiting and may depend upon the desired application. For example, various components may not be required for a desired application or design specification (e.g., for the type of programmable device selected).

Furthermore, it should be understood that the components are illustrated in block form for clarity and that various components would typically be distributed throughout PLD 100, such as in and between logic blocks 104, hard IP blocks 160, and routing resources 180 to perform their conventional functions (e.g., storing configuration data that configures PLD 100 or providing interconnect structure within PLD 100). It should also be understood that the various embodiments disclosed herein are not limited to programmable logic devices, such as PLD 100, and may be applied to various other types of programmable devices, as would be understood by one skilled in the art.

System 130 (e.g., also referred to as an external device) may be used to create a desired user configuration or design of PLD 100 and generate corresponding configuration data. Such configuration data may be stored in PLD 100 as discussed and used by configuration engine 110 to configure various components of PLD 100. In some embodiments, configuration engine 110 may be implemented by processor 132 of external system to provide transactions to PLD 100 through I/O blocks 102, SERDES blocks 150, and/or otherwise as appropriate.

In the illustrated embodiment, system 130 is implemented as a computer system. In this regard, system 130 includes, for example, one or more processors 132 (e.g., implemented by appropriate logic as discussed with regard to configuration engine 110) which may be configured to execute instructions, such as software instructions, provided in one or more memories 134 and/or stored in non-transitory form in one or more non-transitory machine-readable mediums 136 (e.g., a memory or other appropriate storage medium internal or external to system 130). For example, in some embodiments, system 130 may run a PLD configuration application, such as Lattice Diamond System Planner and/or Lattice Radiant software available from Lattice Semiconductor Corporation to permit a user to create a desired configuration and generate corresponding configuration data to program PLD 100.

System 130 also includes, for example, a user interface 135 (e.g., a screen or display) to display information to a user, and one or more user input devices 137 (e.g., a keyboard, mouse, trackball, touchscreen, and/or other device) to receive user commands or design entry to prepare a desired configuration of PLD 100 and/or to identify various triggers used to evaluate the operation of PLD 100, as further described herein.

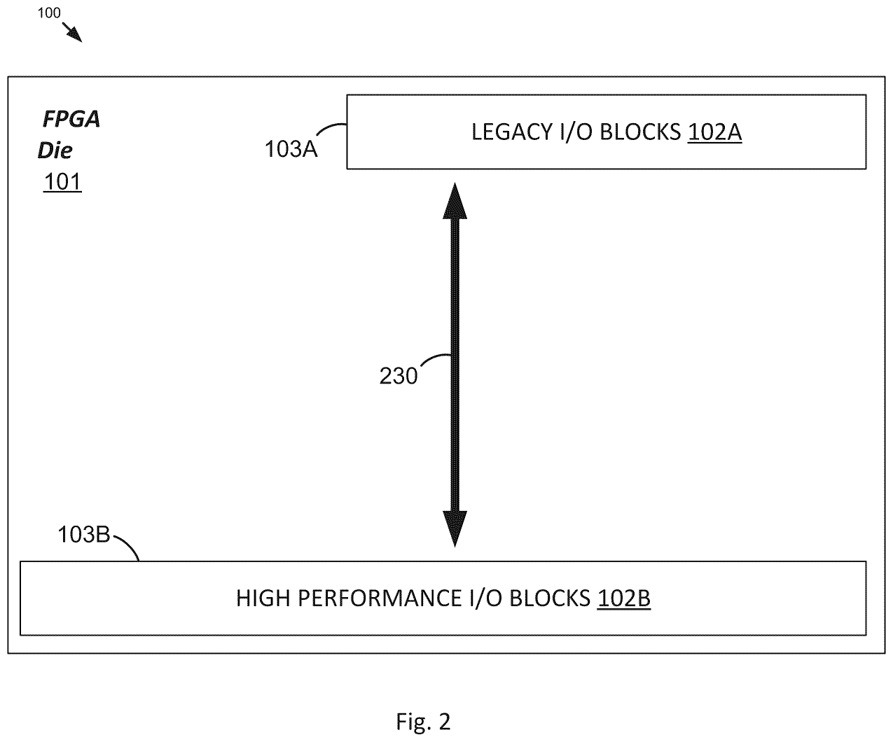

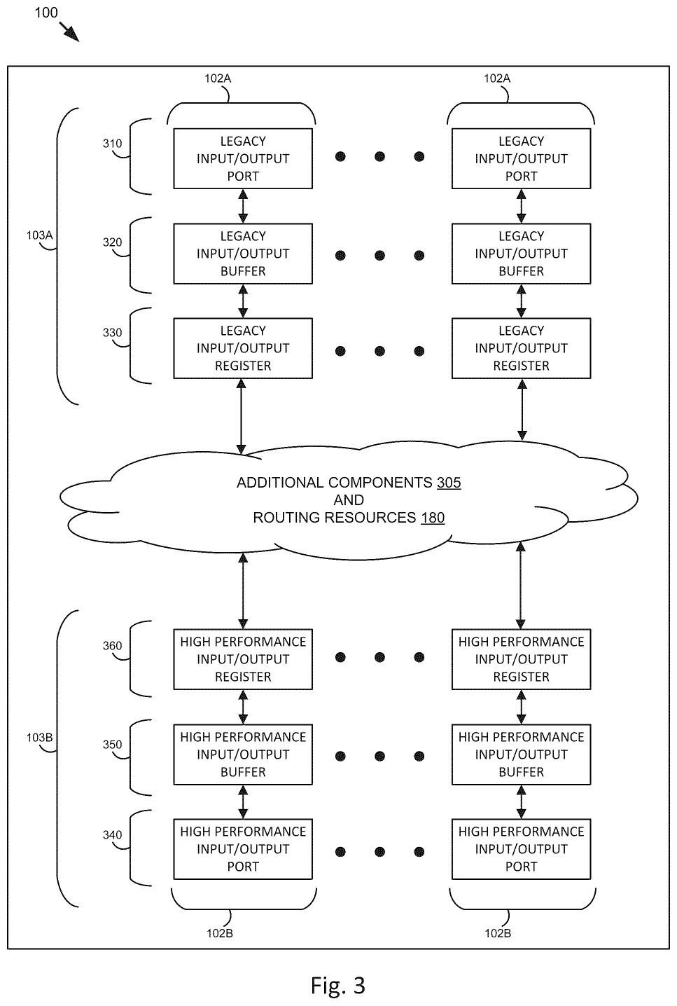

FIG. 2 illustrates a block diagram of PLD 100 implemented on a die 101 with several types of input/output (I/O) blocks 102A and 102B in accordance with an embodiment of the disclosure. I/O blocks 102 previously discussed with regard to FIG. 1 may be implemented in accordance with at least two different types. As shown, these may include legacy I/O blocks 102A and high performance I/O blocks 102B which include previously discussed legacy I/O buffers 320 and high performance I/O buffers 350, respectively. As also shown, I/O blocks 102A and 102B are organized into discrete banks 103A and 103B on die 101 that are physically separated from each other by a distance identified by an arrow 230. In this regard, banks 103A and 103B provide separate sets of physical locations of I/O blocks 102A and 102B, respectively, and including the additional components illustrated in FIG. 3.

FIG. 3 illustrates a block diagram of PLD 100 showing various components of I/O blocks 102A and 102B in accordance with an embodiment of the disclosure. For example, legacy bank 103A includes a plurality of legacy I/O blocks 102A, each of which includes a corresponding legacy I/O port 310, a legacy I/O buffer 320, and a legacy I/O register 330. High performance bank 103B includes a plurality of high performance I/O blocks 102B, each of which includes a corresponding high performance I/O port 340, a high performance I/O buffer 350, and a high performance I/O register 360.

Each of I/O blocks 102A and 102B are connected to additional components 305 of PLD 100 (e.g., any of the various components of PLD 100 discussed herein) and routing resources 180 of PLD 100. In this regard, the various I/O blocks 102A and 102B may be used to send and receive signals (e.g., data, instructions, and/or other information) between additional components 305/routing resources 180 and external devices connected to PLD 100.

For example, each of ports 310 and 340 may be implemented with one or more physical pins to, for example, connect PLD 100 to external devices (e.g., system 130 and/or other devices). Each of I/O buffers 320 and 350 may, for example, adjust associated voltages and/or currents of signals to interface between PLD 100 and external devices in accordance with legacy or high performance specifications as discussed. Each of I/O registers 330 and 360 may store data, instructions, and/or other information that is sent or received through I/O ports 310/340 and I/O buffers 320/350.

In some embodiments, I/O registers 330 and 360 may have different legacy and high performance specifications, respectively, and may therefore be selectively assigned in a similar manner as I/O buffers 320 and 350 discussed herein. Other kinds of physical hardware components (e.g., memories such as embedded block RAM) may have different types (e.g., with different memory sizes) that may also be selectively assign in a similar manner.

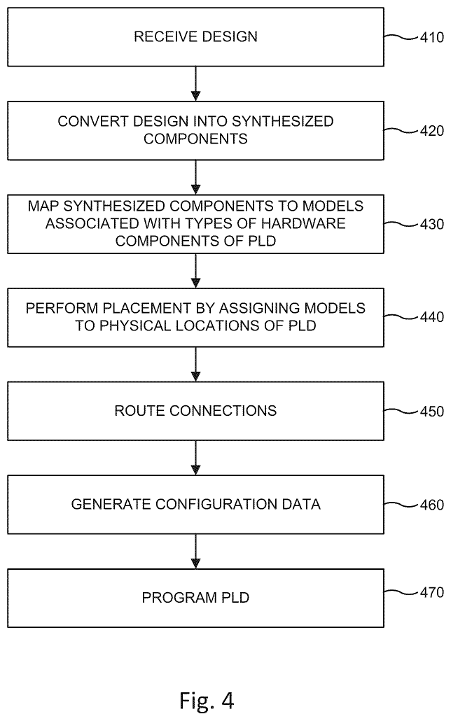

FIG. 4 illustrates a process of implementing a design for PLD 100 in accordance with an embodiment of the disclosure. For example, the process of FIG. 4 may be performed by system 130 running a PLD configuration application such as Lattice Diamond System Planner and/or Lattice Radiant Software as discussed. In some embodiments, the various files and information referenced in FIG. 4 may be stored, for example, in one or more databases and/or other data structures in memory 134, machine readable medium 136, and/or otherwise.

In operation 410, system 130 receives a design that specifies desired functionality of PLD 100. For example, a user may interact with system 130 (e.g., through user input device 137 and hardware description language (HDL) code representing the design) to identify various features of the design (e.g., operations to be performed by PLD 100 when configured and/or other features). In some embodiments, the design may be provided in a register transfer level (RTL) description (e.g., a gate level description). System 130 may perform one or more rule checks to confirm that the design describes a valid configuration of PLD 100. For example, system 130 may reject invalid configurations and/or request the user to provide new design information as appropriate.

In operation 420, system 130 synthesizes the design to convert the design into a plurality of synthesized components (e.g., logical constructs representing operations performed by the design). For example, operation 420 may include converting the design into a netlist (e.g., a synthesized RTL description) identifying an implementation of the design as a plurality of synthesized components (e.g., also referred to as logic components or netlist components). In this regard, the synthesized components may identify logic, hardware functions, and/or other design features that may be subsequently mapped to models of the various physical hardware components of PLD 100 discussed herein. In some embodiments, the netlist may be stored in Verilog format in a Unified Database (UDB) file and/or Electronic Design Interchange Format (EDIF) in a Native Generic Database (NGD) file.

In some embodiments, operation 420 may include performing an optimization process on the design to reduce propagation delays, consumption of PLD resources and interconnections, and/or otherwise optimize the performance of PLD 100 when configured with the design. For example, the optimization process may be performed on the netlist representing the synthesized design to provide an improved netlist representing an improved synthesized design.

In operation 430, system 130 performs a mapping process that identifies models of the physical hardware components of PLD 100 that may be used to implement the various synthesized components identified in operation 420. For example, as discussed, various models may be provided (e.g., stored in memory 134 and/or machine readable medium 136) that are associated with one or more physical hardware components of the PLD (e.g., I/O buffers, programmable logic cells, embedded block RAM, digital signal processor blocks, memories, registers, LUTs, gates, and/or other components discussed herein).

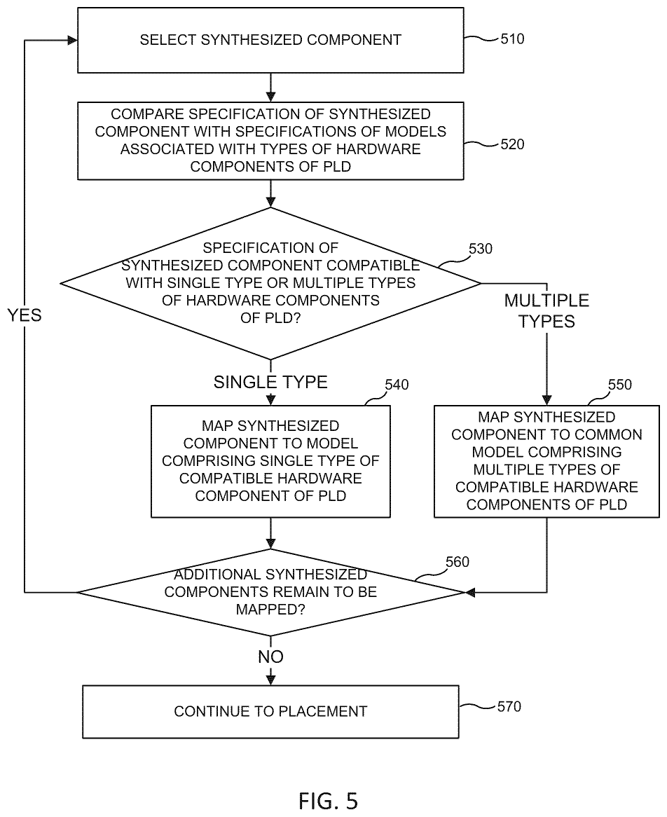

As discussed, if a synthesized component has a specification that may be satisfied by multiple types of physical hardware components, then the synthesized component may be mapped to a multiple type model that is associated with those multiple types of physical hardware components. In contrast, if a synthesized component has a specification that may be satisfied by only a single type of physical hardware component, then the synthesized component may be mapped to a single type model that is associated with only the single type of physical hardware component. Further details regarding the implementation of operation 430 is provided by the process of FIG. 5.

In this regard, FIG. 5 illustrates a process of mapping synthesized components of a design for PLD 100 in accordance with an embodiment of the disclosure. For example, the process of FIG. 5 may be performed by system 130 during operation 430 of FIG. 4.

Referring to FIG. 5, in operation 510, system 130 selects one of the synthesized components identified in operation 420 of FIG. 4. In operation 520, system 130 compares one or more specifications of the synthesized component with the specifications of the various models of the physical hardware components of PLD 100 to identify any models with compatible specifications. For example, in a case where the synthesized component is an I/O buffer, system 130 may compare the one or more specifications required by the synthesized I/O buffer component to available models of I/O buffers associated with PLD 100.

As discussed, PLD 100 includes high performance I/O buffers 350 with high performance specifications, and also includes legacy I/O buffers 320 with associated legacy specifications. Accordingly, a single type high performance I/O buffer model (e.g., a first model) may be provided that is associated with physical hardware components of PLD 100 corresponding to high performance I/O buffers 350 of PLD 100 and their associated high performance specifications. A single type legacy I/O buffer model (e.g., a second model) may be provided that is associated with physical hardware components of PLD 100 corresponding to legacy I/O buffers 320 of PLD 100 and their associated legacy specifications. In addition, a multiple type I/O buffer model (e.g., a common model) may be provided that is associated with physical hardware components of PLD 100 corresponding to both high performance I/O buffers 350 and legacy I/O buffers 320 of PLD 100 and both of their high performance and legacy specifications.

In operation 530, system 130 determines whether the synthesized I/O buffer component is compatible with single or multiple types of physical hardware components of PLD 100. If it is compatible with only a single type of physical hardware component, then the process continues to operation 540. If it is compatible with multiple types of physical hardware components, then the process continues to operation 550.

In operation 540, the synthesized I/O buffer component is mapped to a single type model. Continuing the example above, this may be either the single type high performance first model or the single type legacy second model. In this regard, the synthesized I/O buffer component may have a specification that is compatible with only high performance I/O buffers 350 (e.g., a data rate greater than 100 Mbps) or only legacy I/O buffers 320 (e.g., a large voltage signal greater than 1.8 volts). Accordingly, in each of these cases, the synthesized I/O buffer component may be compatible with only high performance I/O buffers 350 and their associated single type high performance first model or only legacy I/O buffers 320 and their associated single type legacy second model.

In operation 550, the synthesized I/O buffer component is mapped to a multiple type model. Continuing the example above, if the synthesized I/O buffer component is compatible with both high performance I/O buffers 350 and legacy I/O buffers 320 (e.g., a voltage signal in the range of 1.2 volts to 1.8 volts and both low speed data rates of 100 Mbps and high speed data rates of 500 Mbps to 1 Gbps), then the synthesized I/O buffer component is compatible with both high performance I/O buffers 350 and legacy I/O buffers 320 and is also compatible with the multiple type I/O buffer model.

As discussed, the use of the multiple type I/O buffer model addresses various problems associated with conventional approaches as discussed. For example, arbitrarily assigning the synthesized I/O buffer to a high performance I/O buffer 350 or a legacy I/O buffer 320 may be detrimental to the implementation of the design due to the different physical locations of high performance I/O buffers 350 in bank 103B of high performance I/O blocks 102B and legacy I/O buffers 320 in bank 103A of legacy I/O blocks 102A as illustrated and discussed with regard to FIGS. 2 and 3. In particular, arbitrarily selecting one or the other may result in excessively long routing connections with associated latencies. Accordingly, in such cases where the synthesized I/O buffer is compatible with multiple types of I/O buffers 320/350 supported by PLD 100, the multiple type I/O buffer model may be used to provide increased flexibility in implementing the design for PLD 100.

Following operations 540 and 550, the process continues to operation 560 where system 130 determines if additional synthesized components remain to be mapped to corresponding models. If yes, the process returns to operation 510 where another synthesized component is selected for processing. Otherwise, the process proceeds to operation 570 where it continues to the placement process of operation 440 of FIG. 4.

Referring again to FIG. 4, in operation 440, system 130 performs a placement process to assign the models mapped in operation 430 to particular physical hardware components residing at specific physical locations of the PLD 100, and thus determine a layout for the PLD 100. In some embodiments, the placement may be performed on one or more previously-stored UDB and/or NGD files, with the placement results stored as another physical design file.

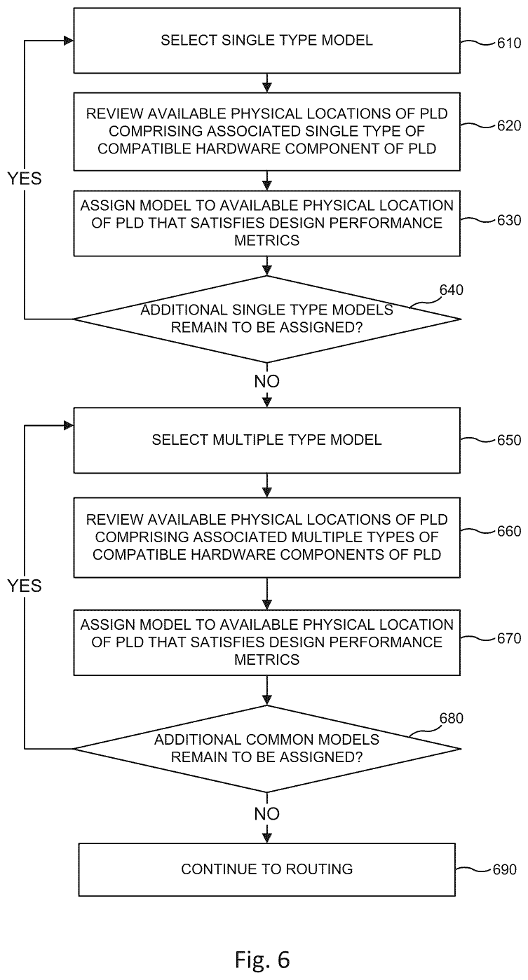

In this regard, FIG. 6 illustrates a process of placing components of a design for PLD 100 in accordance with an embodiment of the disclosure. For example, the process of FIG. 6 may be performed by system 130 during operation 440 of FIG. 4.

As further discussed herein, operations 610 to 640 are performed in relation to single type models, whereas operations 650 to 680 are performed in relation to multiple type models. By performing operations 650 to 680 after operations 610 to 640, the multiple type models may be flexibly assigned without affecting the availability of physical locations for the single type models (e.g. the single type models have fewer available physical locations due to their associations with only a single type of physical hardware component).

Referring now to the single type models, in operation 610, system 130 selects one of the single type models mapped in operation 540 of FIG. 5. For example, in the case of an I/O buffer, a high performance first I/O buffer model or a legacy second I/O buffer model may be selected.

In operation 620, system 130 reviews the available physical locations of PLD 100 that comprise the type of hardware component associated with the selected single type model. For example, if the selected model is a high performance first I/O buffer model for a high performance I/O buffer 350, system 130 reviews the physical locations of high performance I/O buffers 350 available in high performance bank 103B of high performance I/O blocks 102B. If the selected model is a legacy second I/O buffer model for a legacy I/O buffer 320, system 130 reviews the physical locations of legacy I/O buffers 320 available in legacy bank 103A of legacy I/O blocks 102A.

In operation 630, system 130 assigns the single type selected model to one of the available physical locations that satisfies the performance metrics of the design.

In operation 640, system 130 determines if additional single type models remain to be assigned to physical locations. If yes, the process returns to operation 610 where another single type model is selected for processing. Otherwise, the process proceeds to operation 650.

Referring now to the multiple type models, in operation 650, system 130 selects one of the multiple type models mapped in operation 550 of FIG. 5. For example, in the case of an I/O buffer, a multiple type I/O buffer model may be selected.

In operation 660, system 130 reviews the available physical locations of PLD 100 that comprise the type of hardware component associated with the selected multiple type model. For example, if the selected model is a multiple type I/O buffer model, system 130 reviews the physical locations of high performance I/O buffers 350 available in high performance bank 103B of high performance I/O blocks 102B and also reviews the physical locations of legacy I/O buffers 320 available in legacy bank 103A of legacy I/O blocks 102A. In this regard, system 130 reviews all available physical locations for any of I/O buffers 320/350, regardless of whether they are high performance or legacy implementations.

In operation 670, system 130 selectively assigns the selected multiple type I/O buffer model to one of the available physical locations that best satisfies the performance metrics of the design. As discussed, certain physical locations within each of banks 103A or 103B may provide greater or lesser performance depending on the particular placement of other components of the design (e.g., having associated latencies and/or other associated properties).

Because system 130 considers all available physical locations (e.g., that have not already been assigned to single models in operation 630) within both of banks 103A and 103B (e.g., as a result of mapping the synthesized I/O buffer component to a multiple type model compatible with both high performance and legacy specifications of I/O buffers 320 and 350), system 130 has increased flexibility in selecting the physical location that will provide increased performance over conventional approaches that may arbitrarily select from bank 103A without considering bank 103B, or vice versa. For example, a physical location selected in accordance with the techniques of the present disclosure may provide reduced latency over conventional approaches as discussed.

In operation 680, system 130 determines if additional multiple type models remain to be assigned to physical locations. If yes, the process returns to operation 650 where another multiple type model is selected for processing. Otherwise, the process proceeds to operation 690 where it continues to the routing process of operation 450 of FIG. 4.

Referring again to FIG. 4, in operation 450, system 130 performs a routing process to route connections (e.g., using routing resources 180) among the physical hardware components of PLD 100 based on the placement layout determined in operation 440 to realize the physical interconnections among the placed components. In some embodiments, the routing may be performed on one or more previously-stored UDB and/or NGD files, with the routing results stored as another physical design file.

Thus, following operation 450, one or more physical design files may be provided which specify the design after it has been synthesized (e.g., converted and optimized), mapped, placed, and routed for PLD 100 (e.g., by combining the results of the corresponding previous operations). In operation 460, system 130 generates configuration data for the synthesized, mapped, placed, and routed design. In operation 470, system 130 configures PLD 100 with the configuration data by, for example, loading a configuration data bitstream into PLD 100 over connection 140.

Other embodiments are also contemplated. For example, although various aspects of the present disclosure have been discussed in relation to two different types of I/O buffer components, any desired number of types of I/O buffer components may be considered, and other types of PLD components may be processed such as I/O registers 330/360 and/or any other components of PLD 100 discussed herein.

Where applicable, various embodiments provided by the present disclosure can be implemented using hardware, software, or combinations of hardware and software. Also where applicable, the various hardware components and/or software components set forth herein can be combined into composite components comprising software, hardware, and/or both without departing from the spirit of the present disclosure. Where applicable, the various hardware components and/or software components set forth herein can be separated into sub-components comprising software, hardware, or both without departing from the spirit of the present disclosure. In addition, where applicable, it is contemplated that software components can be implemented as hardware components, and vice-versa.

Software in accordance with the present disclosure, such as program code and/or data, can be stored on one or more computer readable mediums. It is also contemplated that software identified herein can be implemented using one or more general purpose or specific purpose computers and/or computer systems, networked and/or otherwise. Where applicable, the ordering of various steps described herein can be changed, combined into composite steps, and/or separated into sub-steps to provide features described herein.

Embodiments described above illustrate but do not limit the invention. It should also be understood that numerous modifications and variations are possible in accordance with the principles of the present invention. Accordingly, the scope of the invention is defined only by the following claims.

What is claimed is:

1. A method comprising:
receiving a design identifying operations to be performed by a programmable logic device (PLD);
converting the operations to a plurality of synthesized components;
mapping a selected one of the synthesized components to a model associated with first and second types of hardware components of the PLD, wherein the selected synthesized component is compatible with first and second specifications of the first and second types of hardware components, respectively; and
assigning the selected synthesized component to a physical location of the PLD comprising either the first type of hardware component or the second type of hardware component to improve a performance metric of the PLD configured with the design.

2. The method of claim 1, wherein:
the first type of hardware component is a first type of I/O buffer;
the first specification comprises a first voltage range and a first data rate range;
the second type of hardware component is a second type of I/O buffer; and
the second specification comprises a second voltage range overlapping the first voltage range and a second data rate range less that the first data rate range.

3. The method of claim 1, wherein:
the PLD comprises a first set of physical locations each comprising an implementation of the first type of hardware component; and
the PLD comprises a second set of physical locations each comprising an implementation of the second type of hardware component.

4. The method of claim 3, wherein the first and second sets of physical locations are discrete from each other and physically separated from each other on a die of the PLD.

5. The method of claim 3, wherein the assigning comprises selecting the physical location from the first set or the second set.

6. The method of claim 3, further comprising:
mapping first and second additional ones of the synthesized components to first and second additional models associated with the first and second types of hardware components of the PLD, respectively; and
assigning the first and second synthesized components to the first and second sets of physical locations, respectively.

7. The method of claim 6, wherein:
the first synthesized component is compatible with the first specification and is not compatible with the second specification; and
the second synthesized component is compatible with the second specification and is not compatible with the first specification.

8. The method of claim 6, wherein the assigning the first and second synthesized components is performed prior to the assigning the selected synthesized component.

9. The method of claim 1, wherein the performance metric is a latency associated with a connection between the assigned physical location and an additional hardware component of the PLD.

10. The method of claim 1, further comprising:
generating configuration data to configure the first and second types of hardware components in accordance with the design; and
programming the PLD with the configuration data.

11. A system comprising:
a processor; and
a memory adapted to store a plurality of computer readable instructions which when executed by the processor are adapted to cause the system to perform a method comprising:
receiving a design identifying operations to be performed by a programmable logic device (PLD),
synthesizing the design into a plurality of synthesized components,
mapping a selected one of the synthesized components to a model associated with first and second types of hardware components of the PLD, wherein the selected synthesized component is compatible with first and second specifications of the first and second types of hardware components, respectively, and
assigning the selected synthesized component to a physical location of the PLD comprising either the first type of hardware component or the second type of hardware component to improve a performance metric of the PLD configured with the design.

12. The system of claim 11, wherein:
the first type of hardware component is a first type of I/O buffer;
the first specification comprises a first voltage range and a first data rate range;
the second type of hardware component is a second type of I/O buffer; and
the second specification comprises a second voltage range overlapping the first voltage range and a second data rate range less that the first data rate range.

13. The system of claim 11, wherein:
the PLD comprises a first set of physical locations each comprising an implementation of the first type of hardware component; and
the PLD comprises a second set of physical locations each comprising an implementation of the second type of hardware component.

14. The system of claim 13, wherein the first and second sets of physical locations are discrete from each other and physically separated from each other on a die of the PLD.

15. The system of claim 13, wherein the assigning comprises selecting the physical location from the first set or the second set.

16. The system of claim 13, wherein the method further comprises:
mapping first and second additional ones of the synthesized components to first and second additional models associated with the first and second types of hardware components of the PLD, respectively; and
assigning the first and second synthesized components to the first and second sets of physical locations, respectively.

17. The system of claim 16, wherein:
the first synthesized component is compatible with the first specification and is not compatible with the second specification; and
the second synthesized component is compatible with the second specification and is not compatible with the first specification.

18. The system of claim 16, wherein the assigning the first and second synthesized components is performed prior to the assigning the selected synthesized component.

19. The system of claim 11, wherein the performance metric is a latency associated with a connection between the assigned physical location and an additional hardware component of the PLD.

20. The system of claim 11, wherein the method further comprises:
generating configuration data to configure the first and second types of hardware components in accordance with the design; and
programming the PLD with the configuration data.
